(19) United States
(12) Patent Application Publication
(10) Pub. No.: US 2026/0148373 A1
(43) Pub. Date: May 28, 2026

(54) SUBSTRATE PROCESSING METHOD AND SUBSTRATE PROCESSING APPARATUS

(71) Applicant: Tokyo Electron Limited, Minato-ku, Tokyo (JP)

(72) Inventors: Yusuke MIYAKUBO, Hsinchu City (TW); Hibiki NAKANO, Kumamoto (JP); Masatoshi KAWAKITA, Kumamoto (JP); Shogo INABA, Kumamoto (JP)

(21) Appl. No.: 19/399,649

(22) Filed: Nov. 25, 2025

(30) Foreign Application Priority Data
Nov. 28, 2024 (JP) 2024-207333
Sep. 8, 2025 (JP) 2025-148536

(51) Int. Cl. G06T 7/00; G06T 7/13; G06T 7/73; H10P 72/00; H10P 74/00

(52) U.S. Cl. CPC G06T 7/001; G06T 7/13; G06T 7/73; H10P 72/0604; H10P 74/23; G06T 2207/10016; G06T 2207/20081; G06T 2207/30148; G06T 2207/30232

(57) ABSTRACT

A substrate processing method includes executing a predetermined process on a substrate, wherein the predetermined process includes rotating the substrate held by a holder, and repeatedly executing a monitoring process during execution of the predetermined process. The monitoring process includes a first process of detecting an outer edge in an image acquired by imaging a range including the outer edge on a front surface of the substrate, a second process of calculating a location of the outer edge in the image based on a detection result of the first process, and a third process of determining whether an abnormality related to holding of the substrate by the holder is present, based on a calculation result of the second process.

### CROSS-REFERENCE TO RELATED APPLICATIONS

This application is based upon and claims the benefit of priority from Japanese Patent Application No. 2025-148536, filed on Sep. 8, 2025, and Japanese Patent Application No. 2024-207333, filed on Nov. 28, 2024, the entire contents of which are incorporated herein by reference.

### BACKGROUND

### Field

The present disclosure relates to a substrate processing method, a monitoring method of substrate processing, a storage medium, and a substrate processing apparatus.

### Description of the Related Art

Japanese Unexamined Patent Publication No. 2023-137511 discloses a substrate processing apparatus including a chamber, a substrate holder that holds a substrate in the chamber, a camera that images an imaging region including a monitored object in the chamber to generate image data, and a control device that monitors a state of the monitored object.

### SUMMARY

Disclosed herein is a substrate processing method. The substrate processing method may include: executing a predetermined process on a substrate, wherein the predetermined process includes rotating the substrate held by a holder; and repeatedly executing a monitoring process during execution of the predetermined process. The monitoring process may include: a first process of detecting an outer edge in an image acquired by imaging a range including the outer edge on a front surface of the substrate; a second process of calculating a location of the outer edge in the image based on a detection result of the first process; and a third process of determining whether an abnormality related to holding of the substrate by the holder is present, based on a calculation result of the second process.

Additionally, a computer-readable storage medium storing a program for causing an apparatus to execute a monitoring method of substrate processing is disclosed herein. The monitoring method includes repeatedly executing a monitoring process while a predetermined process is being performed on a substrate, the predetermined process including rotating the substrate held by a holder. The monitoring process includes a first process of detecting an outer edge in an image acquired by imaging a range including the outer edge on a front surface of the substrate; a second process of calculating a location of the outer edge in the image based on a detection result of the first process; and a third process of determining whether an abnormality related to holding of the substrate by the holder is present, based on a calculation result of the second process.

Additionally, a substrate processing apparatus is disclosed herein. The substrate processing apparatus may include circuitry configured to: perform a predetermined process on a substrate, the predetermined process including rotating the substrate held by a holder; and repeatedly execute a monitoring process during execution of the predetermined process. The monitoring process may include: a first process of detecting an outer edge in an image acquired by imaging a range including the outer edge on a front surface of the substrate; a second process of calculating a location of the outer edge in the image based on a detection result of the first process; and a third process of determining whether an abnormality related to holding of the substrate by the holder is present, based on a calculation result of the second process.

### BRIEF DESCRIPTION OF THE DRAWINGS

FIG. 1 is a plan view schematically illustrating an example of a substrate processing apparatus.

FIG. 2 is a front view schematically illustrating an example of a substrate processing apparatus.

FIG. 3 is a schematic diagram illustrating an example of a liquid processing apparatus.

FIG. 4 is a schematic diagram illustrating an example of an image acquired by an imaging device.

FIG. 5 is a block diagram illustrating an example of a functional configuration of a control device.

FIGS. 6A and 6B are graphs schematically illustrating an example of temporal change in outer edge location.

FIG. 7 is a block diagram illustrating an example of a hardware configuration of a control device.

FIG. 8 is a flowchart illustrating an example of a processing flow executed by a control device.

FIG. 9A is a schematic diagram illustrating an example of an image acquired by an imaging device.

FIG. 9B is a graph schematically illustrating an example of temporal change in distance between a wafer and a cup.

FIG. 10 is a schematic diagram illustrating an example of an image acquired by an imaging device.

FIG. 11 is a schematic diagram illustrating an example of an image acquired by an imaging device.

FIGS. 12A and 12B are schematic diagrams illustrating examples of images acquired by an imaging device.

### DETAILED DESCRIPTION

In the following description, with reference to the drawings, the same reference numbers are assigned to the same components or to similar components having the same function, and overlapping description is omitted. Hereinafter, a wafer processing system as an example of a substrate processing apparatus will be described with reference to the drawings.

### Wafer Processing System

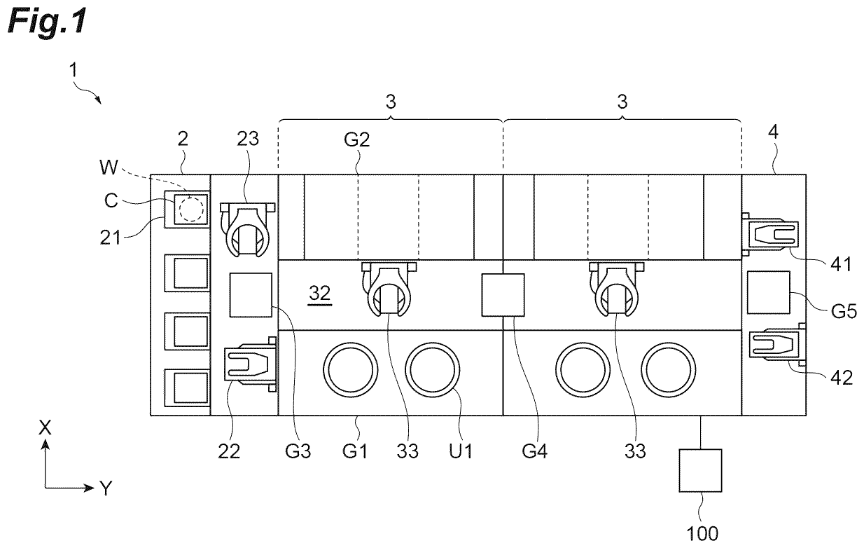

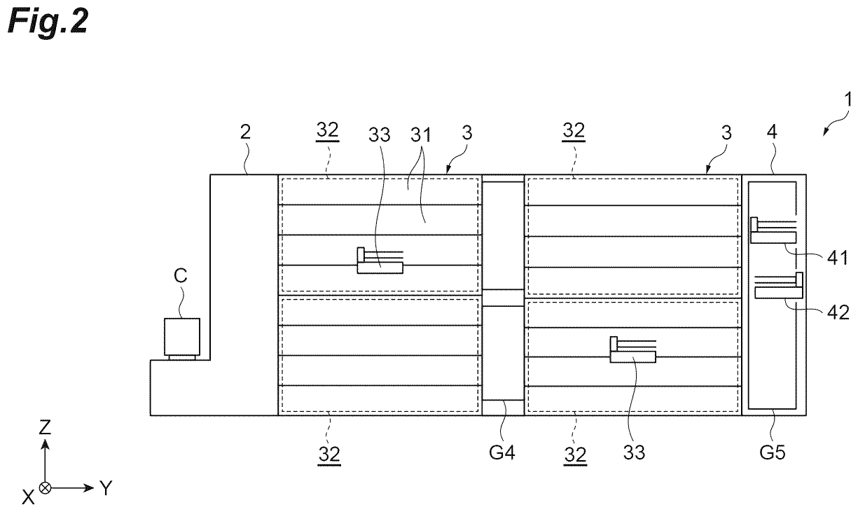

First, the configuration of the wafer processing system according to the present example will be described. FIGS. 1 and 2 are a plan view and a front view, respectively, schematically illustrating an outline of the configuration of the wafer processing system 1. In the present example, a case where the wafer processing system 1 is a photolithography processing system that performs forming operation of a resist film and development operation on wafer W (substrate) will be described as an example.

As illustrated in FIG. 1, the wafer processing system 1 includes a cassette station 2 into and from which cassettes C accommodating a plurality of wafers W are carried, and a processing station 3 including a plurality of various processing apparatuses that perform predetermined processes on the wafers W. The wafer processing system 1 has a configuration in which the cassette station 2, the processing station 3, and an interface station 4 that transfers a wafer W from and to an exposure apparatus (not illustrated) adjacent on the opposite side of the processing station 3 are integrally connected. Although two processing stations 3 are installed between the cassette station 2 and the interface station 4 as illustrated in FIG. 1, one processing station 3 may be provided, or three or more processing stations 3 may be installed.

The cassette station 2 includes a plurality of cassette stages 21 and wafer transfer apparatuses 22 and 23. The cassette station 2 transfers a wafer W between the cassettes C placed on the stages 21 and the processing station 3 by the wafer transfer apparatus 22 or 23. For this purpose, the wafer transfer apparatuses 22 and 23 are each provided with drive mechanisms having movement paths in the horizontal direction (X direction and Y direction), vertical direction (Z direction), and around the vertical axis (θ direction) as necessary, and may be provided with drive mechanisms having movement paths in all directions. At least one of the wafer transfer apparatuses 22 and 23 is capable of transferring wafers W to and from the cassettes C, and is also capable of transferring wafers W to and from the processing station 3. The transfer operation of a wafer W to and from the processing station 3 means, for example, transferring the wafer W to and from a third block G3 including a transfer device accessible by a wafer transfer apparatus 33 in the processing station 3 described later. The third block G3 may include a plurality of transfer devices (not illustrated) arranged in the vertical direction.

An inspection apparatus (not illustrated) that inspects a wafer W may be provided at a position accessible by either the wafer transfer apparatus 22 or 23.

The processing station 3 includes a plurality of blocks, for example, three blocks. The three blocks are a first block G1, a second block G2, and a fourth block G4. As illustrated in FIG. 2, a plurality of layers 31 each including the first block G1 and the second block G2 are stacked in the vertical direction. For example, the first block G1 is provided on the front side (negative X direction side in FIG. 1) of the processing station 3, and the second block G2 is provided on the back side (positive X direction side in FIG. 1) of the processing station 3. The fourth block G4 is provided on the interface station 4 side (positive Y direction side in FIG. 1) of the processing station 3 or at a connection portion with another adjacent processing station 3. The fourth block G4 may include a plurality of transfer devices arranged in the vertical direction. The aforementioned third block G3 may be provided in the processing station 3.

In the first block G1, a plurality of processing apparatuses, for example, a patterning film forming apparatus and a development processing apparatus (both not illustrated) are arranged. The patterning film forming apparatus can include, for example, an antireflection film forming apparatus in addition to a resist film forming apparatus. For example, a plurality of processing apparatuses are arranged side by side in the horizontal direction. The number, arrangement, and types of these processing apparatuses can be arbitrarily selected.

In these patterning film forming apparatuses and development processing apparatuses, for example, a predetermined processing liquid is supplied onto the wafer W, or a predetermined gas is supplied. In this way, the patterning film forming apparatus forms a resist film used as a mask when forming a pattern of a lower layer film, and forms an antireflection film for efficiently performing light irradiation processing such as exposure processing. On the other hand, in the development processing apparatus, a part of the exposed resist film is removed to form an uneven shape as the mask. In the first block G1, a liquid processing apparatus U1 may be arranged as an example of the patterning film forming apparatus. The liquid processing apparatus U1 (processing device) is an apparatus that executes a liquid processing as a predetermined process using a processing liquid for film formation on the wafer W.

For example, in the second block G2, thermal processing apparatuses (not illustrated) that perform thermal processing such as heating and cooling of the wafer W are arranged side by side in the vertical direction and horizontal direction. In the second block G2, although not illustrated, a hydrophobization processing apparatus that performs hydrophobization processing to enhance adhesion between a resist liquid and the wafer W, and a peripheral exposure apparatus that exposes an outer peripheral portion of the wafer W are arranged side by side in the vertical direction (Z direction in FIG. 2) and horizontal direction. The number and arrangement of these thermal processing apparatuses, hydrophobization processing apparatuses, and peripheral exposure apparatuses can also be arbitrarily selected.

As illustrated in FIG. 1, a wafer transfer region 32 is formed in a region disposed between the first block G1 and the second block G2 in plan view. A wafer transfer apparatus 33, for example, is arranged in the wafer transfer region 32.

The wafer transfer apparatus 33 has a transfer arm that is movable, for example, in the Y direction, front-back direction, θ direction, and vertical direction. The wafer transfer apparatus 33 moves within the wafer transfer region 32 and can transfer the wafer W to a predetermined apparatus in the surrounding the first block G1, the second block G2, the third block G3, and the fourth block G4. When there are a plurality of processing stations 3 as illustrated in FIG. 1, the wafer transfer apparatus 33 provided in the processing station 3 located on the interface station 4 side can transfer the wafer W to a predetermined apparatus in a fifth block G5 described later in addition to the first, second, and fourth blocks G1, G2, and G4.

A plurality of wafer transfer apparatuses 33 are arranged vertically, for example, as illustrated in FIG. 2. One wafer transfer apparatus 33 can transfer the wafer W to predetermined apparatus located at the height of a plurality of upper layers 31 among the plurality of layers 31 stacked vertically. For a predetermined apparatus located at the height of a plurality of layers 31 positioned below those layers 31, another wafer transfer apparatus 33 can transfer a wafer W. A plurality of wafer transfer regions 32 are provided to enable such transfer of wafers W. The number of wafer transfer apparatuses 33 and the number of layers 31 corresponding to one wafer transfer apparatus 33 can be arbitrarily selected, such as providing a wafer transfer apparatus 33 for each layer 31.

A shuttle transfer apparatus (not illustrated) may be provided in the wafer transfer region 32, in the first block G1, or in the second block G2. The shuttle transfer apparatus linearly transfers the wafer W between a space adjacent to one side of the processing station 3 and another space adjacent to the opposite side.

in the interface station 4, a fifth block G5 including a plurality of transfer devices, and wafer transfer apparatuses 41 and 42 are provided. The interface station 4 transfers the wafer W between the fifth block G5, where transfer of wafers W is performed by the wafer transfer apparatus 33, and the exposure apparatus using the wafer transfer apparatus 41 or 42. For this purpose, the wafer transfer apparatuses 41 and 42 are each provided with drive mechanisms having movement paths in the horizontal direction (X direction, Y direction), vertical direction (Z direction), and around the vertical axis (θ direction) as necessary, and may be provided with drive mechanisms having movement paths in all directions. At least one of the wafer transfer apparatuses 41 and 42 can support the wafer W and transfer the wafer W between the transfer device in the fifth block G5 and the exposure apparatus.

A cleaning apparatus that cleans the front surface of the wafer W and the aforementioned peripheral exposure apparatus may be provided in the interface station 4 at a position accessible by either of the wafer transfer apparatuses 41 and 42.

The inspection apparatus may be provided in the cassette station 2 as described above, but may also be provided in the processing station 3 and the interface station 4 at positions accessible by any of the transfer arms (33, 41, 42 in FIG. 1 or FIG. 2) provided inside each.

The wafer processing system 1 described above includes a control device 100 (controller). The control device 100 is, for example, a computer and has a program storage. The program storage stores a program for controlling processing of the wafer W in the wafer processing system 1. The program storage also stores a program for controlling the operation of such as the various processing apparatuses and drive systems of transfer apparatuses described above to realize wafer processing in the wafer processing system 1. The program may be recorded on a computer-readable storage medium H and installed in the control device 100 from the storage medium H. The storage medium H may include ROM, RAM, and hard disk, but is not limited in structure or type, and may be transitory or non-transitory. The control device 100 can include portions that store, read, execute programs for realizing wafer processing, and perform communications related thereto, and each portion can be located both inside and outside the wafer processing system 1. The control device 100 may be one or more circuits, and may be provided integrally or partially separately.

### Operation of Wafer Processing System

The wafer processing system 1 is configured as described above. Next, an example of wafer processing performed using the wafer processing system 1 configured as described above will be described.

First, a cassette C accommodating a plurality of wafers W is carried into the cassette station 2 of the wafer processing system 1 and placed on the cassette stage 21. Next, each wafer W in the cassette C is sequentially taken out by the wafer transfer apparatus 22 or 23 and transferred to a transfer device of the third block G3.

The wafer W transferred to the transfer device of the third block G3 is supported by the wafer transfer apparatus 33 and transferred to a hydrophobization processing apparatus provided in the second block G2, where hydrophobization processing is performed. Next, the wafer W is transferred by the wafer transfer apparatus 33 to a resist film forming apparatus (for example, liquid processing apparatus U1), where a resist film is formed on the wafer W, and then transferred to a thermal processing apparatus where pre-bake processing is performed, and then transferred to a transfer device of the fifth block G5. When there are a plurality of processing stations 3 as illustrated in FIGS. 1 and 2, the wafer W is once placed on a transfer device of the fourth block G4 before being transferred to the transfer device of the fifth block G5, and then transferred to and from the plurality of wafer transfer apparatuses 33. The wafer W may be transferred by the wafer transfer apparatus 33 to a peripheral exposure apparatus as necessary, where exposure processing is performed on the peripheral edge portion of the wafer.

The wafer W transferred to the transfer device of the fifth block G5 is transferred by the wafer transfer apparatuses 41 and 42 to the exposure apparatus, where exposure processing is performed in a predetermined pattern. The wafer W may be cleaned by a cleaning apparatus before the exposure processing.

The exposed wafer W is transferred by the wafer transfer apparatuses 41 and 42 to the transfer device of the fifth block G5. Thereafter, the wafer W is transferred by the wafer transfer apparatus 33 to a thermal processing apparatus, where post-exposure bake processing is performed.

The wafer W subjected to post-exposure bake processing is transferred by the wafer transfer apparatus 33 to a development processing apparatus, where development is performed. After development is completed, the wafer W is transferred by the wafer transfer apparatus 33 to a thermal processing apparatus, where post-bake processing is performed.

Thereafter, the wafer W is transferred by the wafer transfer apparatus 33 to the transfer device of the third block G3, and transferred by the wafer transfer apparatus 22 or 23 of the cassette station 2 to the cassette C on a predetermined cassette stage 21. Thus, a series of photolithography processes is completed.

The wafer processing system in the present disclosure is not limited to the configuration and operation described above. For example, in the above-described example, the wafer processing system is directly connected to the exposure apparatus, and wafers W are transferred between the interface station 4 and the exposure apparatus, but the wafer processing system do not need to be directly connected to the exposure apparatus. In that case, for example, after the wafer W is transferred from the cassette station 2 to the processing station 3 and necessary processing is performed, the wafer W is transferred again to the cassette station 2 for unloading outside the system. Among the processing apparatuses mentioned, those that are not necessary do not need to be provided in the wafer processing system, or processing in those apparatuses does not need to be performed. The wafer W may be a single substrate. The wafer processing system may be a system that performs processing on a laminated substrate WL in which two or more unit substrates are bonded to each other. The wafer processing system may have a liquid processing apparatus that performs liquid processing on the laminated substrate WL, and may have a thermal processing apparatus that performs thermal processing on the laminated substrate WL.

### One Example of Liquid Processing Apparatus

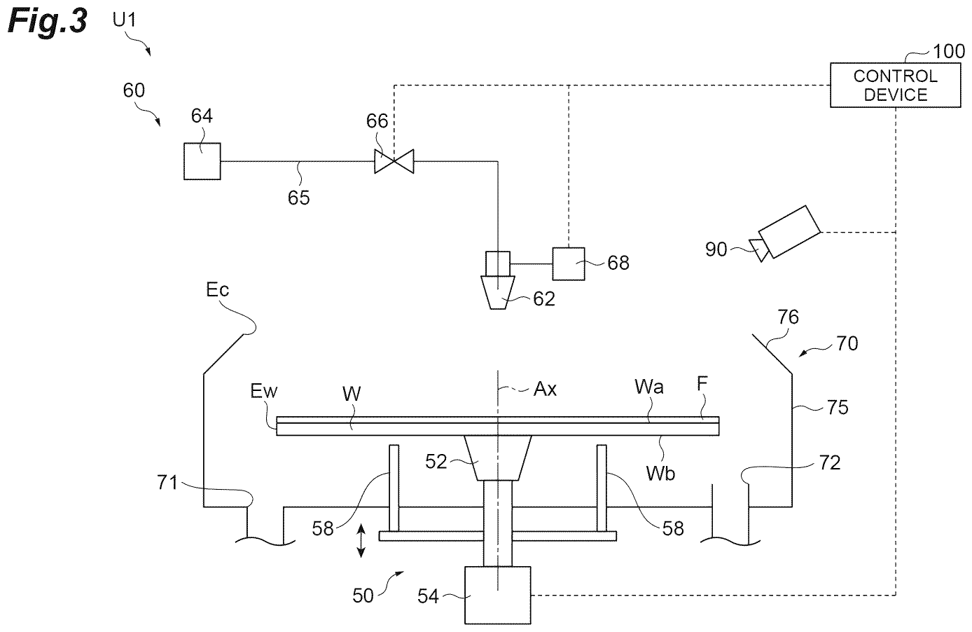

Next, an one example of the liquid processing apparatus U1 will be described with reference to FIG. 3. The liquid processing apparatus U1 supplies a processing liquid for film formation (hereinafter referred to as “processing liquid L1”) to the wafer W to be processed, and forms a film of the processing liquid L1. In FIG. 3, the film of the processing liquid L1 is indicated by “F”. In the present disclosure, a film (coating) of the processing liquid L1 formed by execution of liquid processing by the liquid processing apparatus U1 and a film of the processing liquid L1 formed on the front surface Wa during execution of liquid processing by the liquid processing apparatus U1 are collectively referred to as “film F”.

The liquid processing by the liquid processing apparatus U1 includes rotating the wafer W held by the holder. The liquid processing by the liquid processing apparatus U1 includes supplying the processing liquid L1 to the wafer W held by the holder. The liquid processing apparatus U1 rotates the wafer W during at least a part of the execution period of the liquid processing. The liquid processing apparatus U1, for example, supplies the processing liquid L1 to the front surface Wa of the wafer W while rotating the wafer W, and after supplying the processing liquid L1, rotates the wafer W so as to dry the film F. As illustrated in FIG. 3, the liquid processing apparatus U1 includes, for example, a rotating holder 50, a liquid supplier 60, and a cup 70.

The rotating holder 50 holds and rotates the wafer W. The rotating holder 50 includes a holder 52 and a rotation driver 54. The holder 52 holds (supports) the wafer W. The holder 52, for example, supports a central portion of the back surface Wb of the wafer W arranged horizontally with the front surface Wa facing upward, and holds the wafer W by vacuum suction or the like. The rotation driver 54 is connected to the holder 52 via a shaft.

The rotation driver 54 is an actuator including a power source such as an electric motor, and rotates the holder 52 around a vertical axis Ax. As the holder 52 rotates by the rotation driver 54, the wafer W held (supported) by the holder 52 rotates. The holder 52 holds the wafer W such that the center CP of the wafer W substantially coincides with the axis Ax.

The liquid processing apparatus U1 may have a plurality of (for example, three) lift pins 58. The plurality of lift pins 58 have a function of transferring the wafer W between the holder 52 and the wafer transfer apparatus 33. The plurality of lift pins 58 are arranged around the holder 52. The plurality of lift pins 58 are connected to a drive unit for lifting and are provided so as to be able to move up and down in the vertical direction. For example, when transferring the wafer W to the wafer transfer apparatus 33 after completion of liquid processing, the plurality of lift pins 58 are raised, and the plurality of lift pins 58 support the back surface of the wafer W and move the wafer W to above the holder 52.

The liquid supplier 60 supplies the processing liquid L1 to the front surface Wa of the wafer W. The processing liquid L1 is, for example, a solution (resist) for forming a resist film. The liquid supplier 60 includes a nozzle 62, a supply source 64, a supply pipe 65, an on-off valve 66, and a nozzle driver 68.

The nozzle 62 is configured to discharge the processing liquid L1 onto the front surface Wa of the wafer W held by the holder 52. The nozzle 62 is arranged, for example, above the wafer W (in one example, vertically above the center CP of the wafer W), and discharges the processing liquid L1 vertically downward. The supply source 64 is connected to the nozzle 62 via the supply pipe 65, and supplies the processing liquid L1 to the nozzle 62.

The on-off valve 66 is provided in the supply pipe 65, and switches the open/closed state of the flow path formed by the supply pipe 65. The nozzle driver 68 moves the nozzle 62 between a discharge position above the wafer W and a standby position different from the discharge position. The standby position is set, for example, outside the outer edge Ew of the wafer W. The nozzle driver 68 may move the nozzle 62 in the vertical direction in addition to the direction along the front surface Wa of the wafer W.

The cup 70 is a member that is arranged so as to surround the holder 52 and receives the processing liquid L1 after being supplied to the wafer W (front surface Wa). The cup 70 forms an accommodation space with an open upper end. The holder 52 is located in the accommodation space, and the processing liquid L1 is supplied to the front surface Wa of the wafer W in a state where the wafer W is arranged in the accommodation space. The cup 70 is configured to collect the processing liquid L1 scattered around from the wafer W rotated by the rotating holder 50.

A drain port 71 and an exhaust port 72 are provided at the bottom of the cup 70. The drain port 71 is an opening for discharging the processing liquid L1 collected by the cup 70 to the outside of the cup 70. The exhaust port 72 is an opening for discharging gas in the cup 70 to the outside of the cup 70. For example, gas generated with the supply of the processing liquid L1 to the wafer W is discharged from the exhaust port 72.

The cup 70 includes a peripheral wall 75 and an inclined wall 76. The peripheral wall 75 is formed in a cylindrical shape so as to extend along the circumferential direction around the axis Ax. The peripheral wall 75 is connected to the outer peripheral edge of the bottom of the cup 70, and extends along a direction parallel to the axis Ax. The inclined wall 76 has one end connected to the upper end of the peripheral wall 75, and is inclined so as to extend from the connection point with the upper end of the peripheral wall 75 toward the axis Ax. The inclined wall 76 is formed in an annular shape.

When viewed from the axial direction in which the axis Ax extends (for example, when viewed from vertically above), the inner edge Ec of the cup 70 is located outside the outer edge Ew of the wafer W held by the holder 52. The inner edge Ec of the cup 70 corresponds to, for example, the inner edge of the inclined wall 76, and the outer edge Ew (peripheral edge) of the wafer W corresponds to, for example, the peripheral edge of the film F formed on the front surface Wa of the wafer W.

### Imaging Device

The wafer processing system 1 includes an imaging device 90. The imaging device 90 acquires image data representing a state of processing during execution of a predetermined process (for example, liquid processing) on the wafer W. The imaging device 90 may acquire image data to record the state of processing. The imaging device 90 is, for example, a camera that generates video data. The imaging device 90 is provided in the housing of the liquid processing apparatus U1.

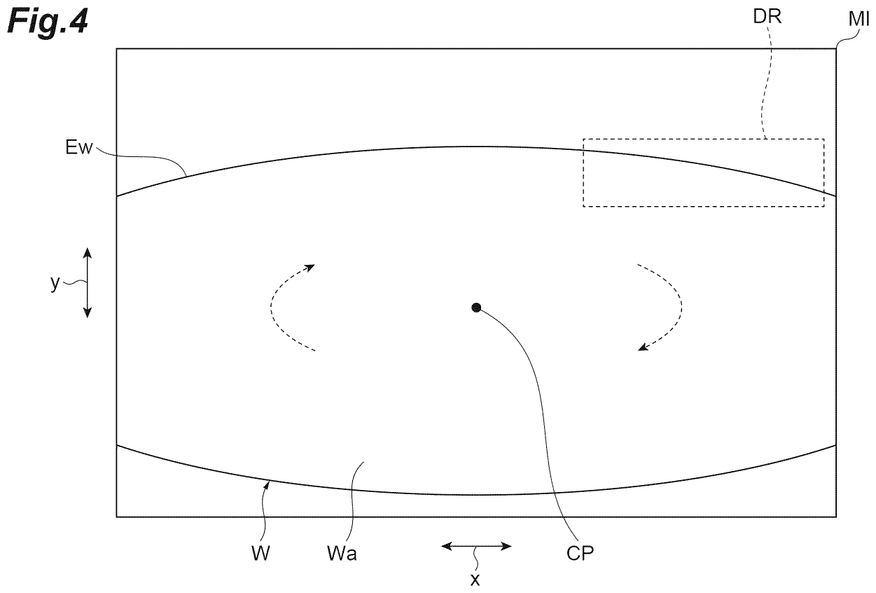

The imaging device 90 can image an imaging range including at least a part of the outer edge Ew of the wafer W held by the holder 52. The imaging device 90 may be installed so as to be able to image the front surface Wa of the wafer W held by the holder 52 from obliquely above. The field of view (imaging range) of the imaging device 90 may be set to include the entire front surface Wa of the wafer W, or may be set to include the center CP of the front surface Wa of the wafer W and a part of the outer edge Ew. FIG. 4 schematically illustrates an image MI (one frame in a moving image) acquired by the imaging device 90.

### Control Device

The control device 100 controls one or more apparatuses included in the wafer processing system 1. The control device 100 may control the liquid processing apparatus U1 so that liquid processing is performed on the wafer W to be processed. The control device 100 (monitoring device) may have a function of monitoring the processing status by the liquid processing apparatus U1 or the like in addition to controlling apparatuses such as the liquid processing apparatus U1. Monitoring the processing status means monitoring whether an abnormality has occurred in the process to be monitored (for example, liquid processing by the liquid processing apparatus U1).

The process to be monitored by the control device 100 may be a process (liquid processing) that is continuously executed from when the wafer W to be processed is placed on the holder 52 until the wafer W is unloaded from the holder 52. The process to be monitored by the control device 100 may include a process in which the plurality of lift pins 58 raise and lower the wafer W, and a process in which the wafer W is transferred from the plurality of lift pins 58 to the wafer transfer apparatus 33 after raising the wafer W. In the process to be monitored, for example, supplying the processing liquid L1 to the front surface Wa while rotating the wafer W by the rotating holder 50, and rotating the wafer W by the rotating holder 50 after stopping the supply of the processing liquid L1 are included. Hereinafter, the content of the present disclosure will be described using a case where the process to be monitored is liquid processing by the liquid processing apparatus U1 as an example.

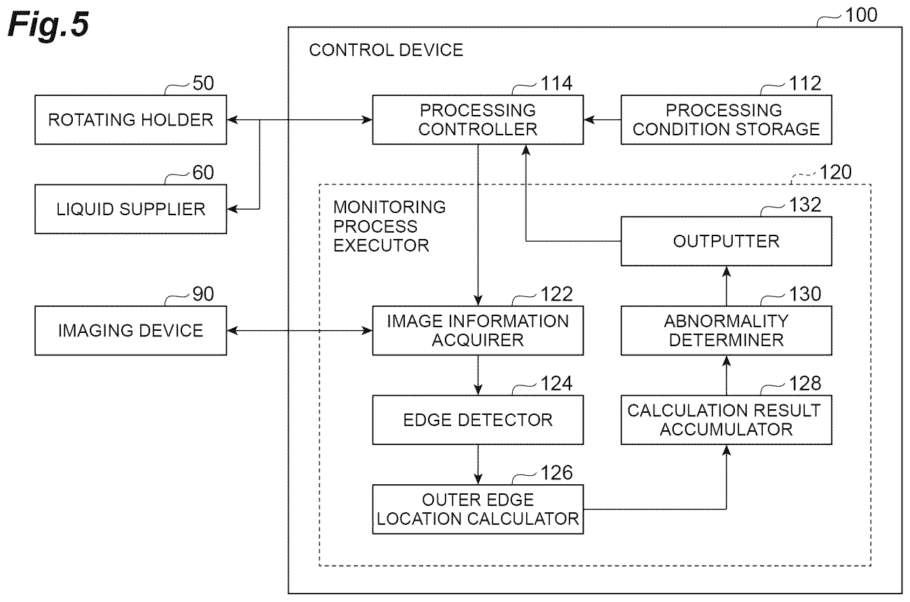

As illustrated in FIG. 5, the control device 100 has, as functional configurations (hereinafter referred to as “functional blocks”), a processing condition storage 112, a processing controller 114, and a monitoring process executor 120. The processes executed by these functional blocks correspond to processes executed by the control device 100.

The processing condition storage 112 stores (save) information indicating conditions for liquid processing by the liquid processing apparatus U1. The conditions for liquid processing stored by the processing condition storage 112 include, for example, the rotation speed of the wafer W, the discharge flow rate of the processing liquid L1, the discharge time of the processing liquid L1, and the rotation time of the wafer W after stopping the discharge of the processing liquid L1. These conditions may be set in advance by an operator or the like.

The processing controller 114 controls the rotating holder 50 and the liquid supplier 60 included in the liquid processing apparatus U1 according to the conditions for liquid processing stored by the processing condition storage 112. The processing controller 114, for example, controls the rotating holder 50 so that the wafer W rotates according to the set value of the rotation speed defined in the conditions for liquid processing. The set value of the rotation speed of the wafer W may be set to a different value for each operation (unit process) included in the liquid processing.

The monitoring process executor 120 repeatedly executes the following monitoring process during execution of liquid processing by the liquid processing apparatus U1. The monitoring process includes a first process, a second process, and a third process. The first process is a process of detecting the outer edge Ew in an image MI acquired by imaging a range including the outer edge Ew on the front surface Wa of the wafer W. The second process is a process of calculating the location of the outer edge Ew in the image MI based on the detection result of the first process. The third process is a process of determining whether an abnormality related to holding of the wafer W by the holder 52 is present, based on the calculation result of the second process. The control device 100 may execute the monitoring process at a predetermined monitoring cycle (for each monitoring cycle).

The monitoring process executor 120 includes, as functional blocks, for example, an image information acquirer 122, an edge detector 124, an outer edge location calculator 126, a calculation result accumulator 128, an abnormality determiner 130, and an outputter 132. The processes executed by these functional blocks correspond to processes executed by the monitoring process executor 120 (control device 100).

The image information acquirer 122 acquires image data for executing the monitoring process from the imaging device 90. The image information acquirer 122, for example, continues to acquire video data generated by imaging with the imaging device 90 while liquid processing by the liquid processing apparatus U1 is continued.

The edge detector 124 executes the first process described above for each monitoring cycle. The edge detector 124 detects an edge corresponding to the outer edge Ew of the wafer W in the image MI included in the video data acquired by the image information acquirer 122. The image MI is different for each monitoring cycle, and the image MI used in a certain monitoring cycle may be an image (still image) of a frame in the monitoring cycle among the video data generated by the imaging device 90.

As illustrated in FIG. 4, the edge detector 124 may extract a partial region of the image MI and detect an edge in the partial region. In FIG. 4, the partial region to be subjected to edge detection is indicated by “DR”, and hereinafter, this region is referred to as “detection target region DR”. A specific algorithm for detecting an edge corresponding to the outer edge Ew of the wafer W is not particularly limited, but the edge detector 124 may detect an edge by, for example, the Canny method.

In detecting an edge corresponding to the outer edge Ew of the wafer W, the edge detector 124 specifies coordinates of pixels where an edge exists in the detection target region DR. The edge detector 124 specifies coordinates of a plurality of points (a plurality of pixels) as coordinates of pixels where an edge exists. The coordinates of each pixel are specified, for example, by the number of pixels from reference locations in the horizontal direction and vertical direction on the image. In FIG. 4, the horizontal direction on the image is indicated by an arrow labeled “x”, and the vertical direction on the image is indicated by an arrow labeled “y”.

The outer edge location calculator 126 executes the second process described above for each monitoring cycle. The outer edge location calculator 126 calculates the location of the outer edge Ew of the wafer W in the image MI based on the edge detection result by the edge detector 124. Calculating the location of the outer edge Ew of the wafer W in the detection target region DR corresponds to calculating the location of the outer edge Ew of the wafer W in the image MI.

At the stage when the edge detector 124 detects an edge, a plurality of points are detected as edges. Therefore, the outer edge location calculator 126 calculates the location of the outer edge Ew of the wafer W from the coordinates of the plurality of points detected by the edge detector 124. The outer edge location calculator 126 may calculate the location of the outer edge Ew based on coordinates of a plurality of points detected as outer edge Ew in the first process. The outer edge location calculator 126 may calculate the average value (arithmetic mean) of the coordinates of the plurality of points detected as edges by the edge detector 124 as the location of the outer edge Ew of the wafer W. The outer edge location calculator 126 may obtain the arithmetic mean of the coordinates of all the plurality of points (coordinates of a plurality of representative points) detected as edges by the edge detector 124 as the location of the outer edge Ew of the wafer W, or may calculate the arithmetic mean of coordinates of some of all pixels detected as edges by the edge detector 124.

The outer edge location calculator 126, for example, calculates the location of the outer edge Ew of the wafer W in at least one of the horizontal direction and vertical direction on the image. The outer edge location calculator 126 may calculate the location of the outer edge Ew of the wafer W for each of the horizontal direction and vertical direction on the image. In this case, the outer edge location calculator 126 obtains the average value of the coordinates in the horizontal direction of the plurality of points detected as edges, and obtains the average value of the coordinates in the vertical direction of the plurality of points detected as edges. The outer edge location calculator 126 may calculate, as the location of the outer edge Ew of the wafer W, the Euclidean distance from a reference location in the image (straight-line distance between the reference location and the coordinates) instead of or in addition to the location of the outer edge Ew in at least one of the horizontal direction and vertical direction on the image.

The calculation result accumulator 128 accumulates the calculation result (calculation result in the second process) calculated by the outer edge location calculator 126 for each monitoring cycle. By the calculation result accumulator 128 accumulating the calculation result for each monitoring cycle, waveform information representing the temporal change in the location of the outer edge Ew of the wafer W (hereinafter simply referred to as “outer edge location”) is obtained.

The abnormality determiner 130 executes the third process described above for each monitoring cycle. The abnormality determiner 130 determines, for each monitoring cycle, whether an abnormality related to holding of the wafer W by the holder 52 is present during execution of liquid processing, based on the calculation result of the outer edge location by the outer edge location calculator 126. The monitoring cycle may be set to a time shorter than the time for the wafer W to rotate one revolution during liquid processing by the liquid processing apparatus U1.

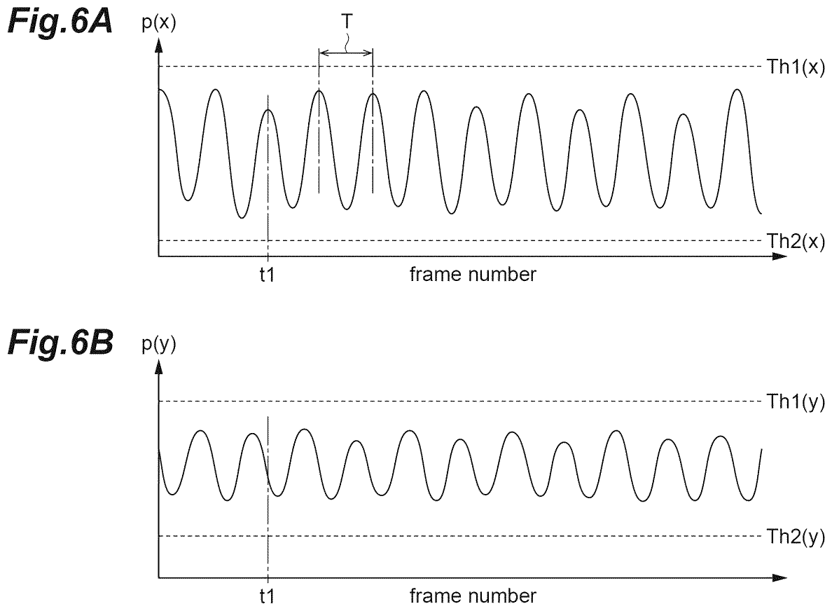

Here, the reason why an abnormality during processing can be detected from the calculation result of the outer edge location of the wafer W will be described with reference to FIGS. 6A and 6B. FIG. 6A illustrates the temporal change in the calculation result of the location of the outer edge Ew of the wafer W in the horizontal direction (x direction), and FIG. 6B illustrates the temporal change in the calculation result of the location of the outer edge Ew of the wafer W in the vertical direction (y direction). For each monitoring cycle, the rotation angle of the wafer W included in the image MI at that timing varies. In FIGS. 6A and 6B, the horizontal axis of the graph is “frame number”, which represents the number of frames of the video data, but substantially represents time. Focusing on the detection target region DR, the difference in the rotation angle of the wafer W means that the part (range) of the outer edge Ew of the wafer W included in the detection target region DR is different.

Assuming that the outer edge Ew of the wafer W is an ideal perfect circle and the center CP of the wafer W completely coincides with the axis Ax representing the rotation center by the rotating holder 50, the outer edge location in the detection target region DR does not change even if the rotation angle of the wafer W is different. On the other hand, the wafer W has some warpage, and the center CP of the wafer W in the state held by the holder 52 and the axis Ax do not strictly coincide. Therefore, the outer edge location in the detection target region DR changes for each monitoring cycle.

Since the wafer W is rotating, as illustrated in FIGS. 6A and 6B, the outer edge location in the detection target region DR changes periodically. If the degree of periodic change in the outer edge location caused by warpage of the wafer W or displacement (eccentricity) of the center CP with respect to the axis Ax is small, it does not become a major trouble. However, if the degree of periodic change in the outer edge location is large from the initial stage of processing or becomes large during processing, there is a possibility that some abnormality has occurred in holding of the wafer W. If processing is continued in a state where such an abnormality has occurred, holding of the wafer W may be released, and trouble may occur. Examples of such trouble during processing include damage to the wafer W itself, and contamination by the processing liquid in the apparatus accompanying the damage or accompanying the release of holding even without damage occurring.

From the above, the idea is obtained that an abnormality related to holding of the wafer W by the holder 52 can be detected by monitoring the size (amplitude) of the outer edge location of the wafer W or the temporal change in the outer edge location of the wafer W. Hereinafter, an abnormality related to holding of the wafer W by the holder 52 is simply referred to as “abnormality”. Detection of an abnormality includes not only detecting the abnormal state itself but also detecting a sign of becoming an abnormal state. The abnormality determiner 130 determines, for each monitoring cycle, whether an abnormality is present by determining whether the calculation result of the outer edge location in the second process in that cycle, or the result of accumulating the calculation results of the outer edge location up to that cycle, satisfies a certain condition.

The abnormality determiner 130, for example, determines whether an abnormality is present based on a comparison result between the outer edge location calculated in the second process and a predetermined threshold value. The abnormality determiner 130, for example, determines that an abnormality has occurred for each monitoring cycle when the calculated value of the outer edge location in the second process in that cycle exceeds a first threshold value or falls below a second threshold value smaller than the first threshold value. The first threshold value and the second threshold value may be determined by prior experiments or the like. By the abnormality determiner 130 detecting an abnormality, prevention of trouble such as damage to the wafer W can be achieved.

When the outer edge location is calculated in each of the horizontal direction and vertical direction on the image in the second process, the abnormality determiner 130 may determine whether an abnormality is present based on the calculation result of the corresponding outer edge location in each of the horizontal direction and vertical direction. The abnormality determiner 130 may determine that an abnormality has occurred when a condition for determining an abnormality is satisfied in at least one of the horizontal direction and vertical direction.

In FIG. 6A, the outer edge location (calculated value) in the horizontal direction is indicated by “p(x)”, the first threshold value is indicated by “Th1(x)”, and the second threshold value is indicated by “Th2(x)”. Also, the time corresponding to the current monitoring cycle is indicated by “t1”. The abnormality determiner 130 may determine that an abnormality has occurred when the outer edge location p(x) at time t1 is greater than the first threshold value Th1(x) or smaller than the second threshold value Th2(x). The abnormality determiner 130 may determine that no abnormality has occurred when the outer edge location p(x) at time t1 is less than or equal to the first threshold value Th1(x) and greater than or equal to the second threshold value Th2(x).

In FIG. 6B, the outer edge location (calculated value) in the vertical direction is indicated by “p(y)”, the first threshold value is indicated by “Th1(y)”, and the second threshold value is indicated by “Th2(y)”. The abnormality determiner 130 may determine that an abnormality has occurred when the outer edge location p(y) at time t1 is greater than the first threshold value Th1(y) or smaller than the second threshold value Th2(y). The abnormality determiner 130 may determine that no abnormality has occurred when the outer edge location p(y) at time t1 is less than or equal to the first threshold value Th1(y) and greater than or equal to the second threshold value Th2(y).

The first threshold value Th1(x) and the first threshold value Th1(y) may be set to the same value or may be set to different values. The second threshold value Th2(x) and the second threshold value Th2(y) may be set to the same value or may be set to different values. The abnormality determiner 130 determining that an abnormality has occurred corresponds to the abnormality determiner 130 detecting an abnormality.

The outputter 132 outputs a signal indicating that an abnormality has been detected (hereinafter referred to as “abnormality signal”) when the abnormality determiner 130 determines that an abnormality has occurred. When the abnormality determiner 130 determines that an abnormality has occurred, the outputter 132 outputs the abnormality signal while liquid processing is continuing. The outputter 132 may output the abnormality signal to the processing controller 114.

When receiving the abnormality signal, the processing controller 114 may control the rotating holder 50 to reduce the speed of rotating the wafer W held by the holder 52 during execution of the liquid processing to be monitored. Alternatively, when receiving the abnormality signal, the processing controller 114 may control the rotating holder 50 to stop rotation of the wafer W held by the holder 52. In addition to the processing controller 114, the outputter 132 may notify an operator or the like of detection of an abnormality by outputting the abnormality signal to an output device connected to the control device 100.

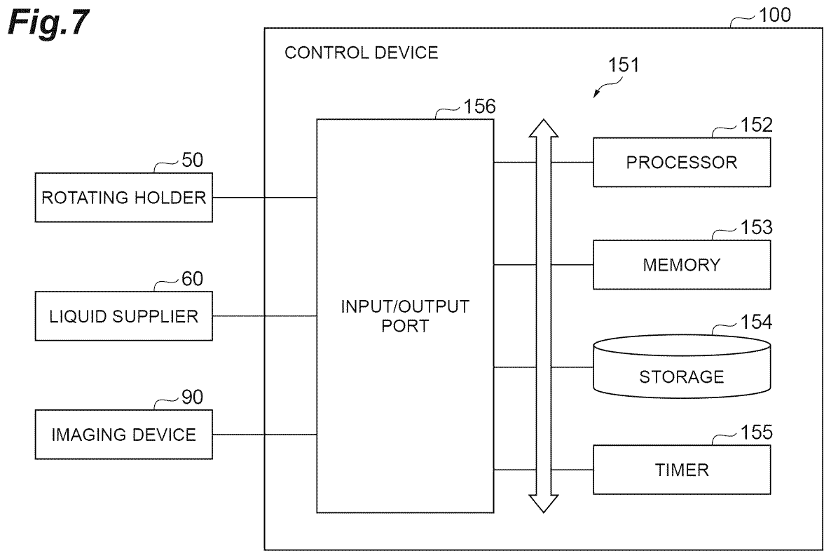

FIG. 7 is a block diagram illustrating a hardware configuration of the control device 100. As illustrated in FIG. 7, the control device 100 has circuitry 151. The circuitry 151 has a processor 152, a memory 153, a storage 154, a timer 155, and an input/output port 156.

The storage 154 is configured by one or more non-volatile memory devices such as flash memory or hard disk. The storage 154 stores a program for causing the wafer processing system 1 (apparatus) to execute a substrate processing method described later. The storage 154 may store a program for causing the control device 100 (apparatus) to execute a monitoring method of substrate processing. The memory 153 is configured by one or more volatile memory devices such as random-access memory. The memory 153 temporarily stores a program loaded from the storage 154.

The processor 152 is configured by one or more arithmetic devices such as a central processing unit (CPU) or a graphics processing unit (GPU). The processor 152 executes the program loaded in the memory 153. The calculation results by the processor 152 are temporarily stored in the memory 153. The timer 155 measures elapsed time by counting clock pulses. The input/output port 156 inputs and outputs electrical signals to and from the rotating holder 50, the liquid supplier 60, the imaging device 90, and the like in response to requests from the processor 152.

### Substrate Processing Method

Next, a substrate processing method executed in the wafer processing system 1 will be described. This substrate processing method includes a processing operation and a monitoring operation (monitoring method of substrate processing). The processing operation is an operation of performing liquid processing including rotating the wafer W held by the holder 52 on the wafer W. The monitoring operation is an operation of repeatedly executing the monitoring process described above during execution of the processing operation.

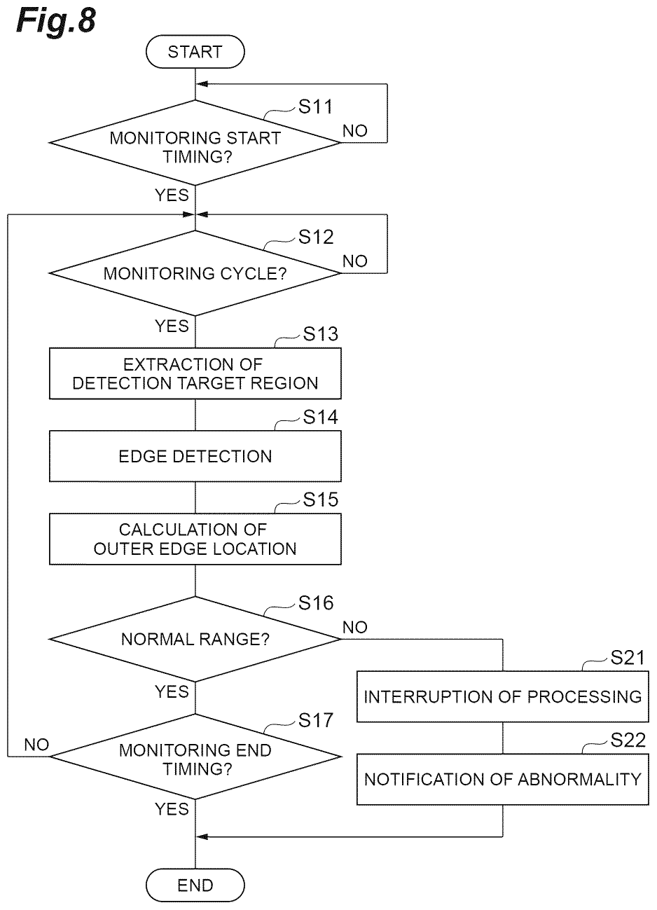

FIG. 8 illustrates an example of a processing flow executed by the control device 100. While the processing flow is being executed, imaging by the imaging device 90 is continued. The control device 100 first executes operation S11 in a state where liquid processing by the liquid processing apparatus U1 has started. In operation S11, for example, the monitoring process executor 120 waits until a preset monitoring start timing. The monitoring start timing may be set to match the start timing of an operation of performing rotation to dry the film F by stopping supply of the processing liquid L1 in the liquid processing.

Next, the control device 100 executes operation S12. In operation S12, for example, the monitoring process executor 120 waits until a monitoring cycle representing a cycle for executing the monitoring process. The monitoring cycle may be set so that the monitoring process is executed each time a still image of one frame is obtained, or may be set so that the monitoring process is executed each time still images of a plurality of frames are obtained.

Next, the control device 100 executes operations S13 and S14. In operation S13, for example, the edge detector 124 extracts the detection target region DR from the image MI. The range of the detection target region DR may be set in advance by an operator or the like. In operation S14, for example, the edge detector 124 detects an edge corresponding to the outer edge Ew in the detection target region DR. In one example, the edge detector 124 detects an edge by the Canny method.

Next, the control device 100 executes operation S15. In operation S15, for example, the outer edge location calculator 126 calculates the location of the outer edge Ew (outer edge location) in the detection target region DR from the coordinates of the plurality of points detected as edges in operation S14. Each pixel detected as an edge has coordinates in the horizontal direction and vertical direction. In one example, the outer edge location calculator 126 calculates the outer edge location in the horizontal direction by obtaining the average value of the coordinates in the horizontal direction of the plurality of points detected as edges. Also, the outer edge location calculator 126 calculates the outer edge location in the vertical direction by obtaining the average value of the coordinates in the vertical direction of the plurality of points detected as edges.

Next, the control device 100 executes operation S16. In operation S16, for example, the abnormality determiner 130 determines whether the outer edge location calculated in operation S15 is in a normal range. Whether it is in the normal range is determined, for example, by comparing the outer edge location with the first threshold value and the second threshold value described above. In one example, the abnormality determiner 130 determines that an abnormality has occurred when the outer edge location calculated in operation S15 deviates from the normal range in at least one of the horizontal direction and vertical direction on the image. The abnormality determiner 130 determines that no abnormality has occurred when the outer edge location calculated in operation S15 is included in the normal range in both the horizontal direction and vertical direction on the image.

In operation S16, when it is determined that the outer edge location calculated in operation S15 deviates from the normal range (operation S16: NO), the process executed by the control device 100 proceeds to operation S21. In operation S21, for example, the outputter 132 outputs the abnormality signal to the processing controller 114, and the processing controller 114 controls the rotating holder 50 to stop rotation of the wafer W. As a result, the liquid processing being monitored is interrupted.

After execution of operation S21, the control device 100 executes operation S22. In operation S22, for example, the outputter 132 notifies that an abnormality has occurred by outputting the abnormality signal to an output device connected to the control device 100.

On the other hand, in operation S16, when it is determined that the outer edge location calculated in operation S15 is included in the normal range (operation S16: YES), the process executed by the control device 100 proceeds to operation S17. In operation S17, for example, the monitoring process executor 120 determines whether it is a preset monitoring end timing. The monitoring end timing may be set to match the end timing of a operation of performing rotation to dry the film F by stopping supply of the processing liquid L1.

In operation S17, when it is determined that it is not the monitoring end timing (operation S17: NO), the process executed by the control device 100 returns to operation S12, and the control device 100 executes a series of processes including operations S12 to S16 again. On the other hand, in operation S17, when it is determined that it is the monitoring end timing (operation S17: YES), the processing flow ends.

In the above processing flow, a series of processes including operations S12 to S15 is repeatedly executed until the monitoring end timing. If the calculated value of the outer edge location deviates from the normal range while the series of processes is being repeatedly executed, the processing is interrupted. As a result, it may be possible to avoid continuing liquid processing (for example, rotation to dry the film F) in a state where there is a possibility that an abnormality has occurred in holding by the holder 52. The control device 100 may execute the above processing flow for a subsequent wafer W as well. That is, the control device 100 may execute the above processing flow each time liquid processing by the liquid processing apparatus U1 is executed for each of a plurality of wafers W.

### Modifications

The processing flow illustrated in FIG. 8 is an example and can be changed as appropriate. In the above processing flow, the control device 100 may execute one operation and the next operation in parallel, or may execute each operation in an order different from the above example. The control device 100 may execute processing with content different from the above example instead of any operation or in addition to the above processing flow. Apart from the above processing flow, the control device 100 may monitor or record the processing status in liquid processing using the image MI itself (entire of the image MI) without focusing on the detection target region DR.

In the determination of whether an abnormality has occurred in operation S16, not only the outer edge location calculated in the current monitoring cycle but also the outer edge location calculated in a monitoring cycle before the current time may be considered. For example, the abnormality determiner 130 may determine whether an average value of the calculated values of the outer edge location in a plurality of monitoring cycles including the current monitoring cycle is in the normal range.

The abnormality determiner 130 may determine that an abnormality has occurred when the calculated value of the outer edge location in each cycle is not in the normal range in a plurality of monitoring cycles including the current monitoring cycle (for example, two or more consecutive monitoring cycles).

The method of determining whether an abnormality has occurred is not limited to comparison between the calculated value of the outer edge location and a threshold value. The abnormality determiner 130 may determine whether an abnormality is present based on waveform information (temporal change in outer edge location) accumulated in the calculation result accumulator 128. As described above, the outer edge location on the image changes periodically with rotation of the wafer W. Therefore, unless an abnormality occurs, the periodic change in the outer edge location on the image is considered to depend on the rotation speed of the wafer W.

In one example, in the third process, the abnormality determiner 130 calculates a frequency in waveform information representing the temporal change in the outer edge location obtained before (up to) the execution time of the third process. As illustrated in FIG. 6A, the abnormality determiner 130 may calculate an interval T between adjacent peaks in the waveform information and obtain the frequency from the interval T. Alternatively, the abnormality determiner 130 may convert the waveform information into a frequency spectrum by Fourier transform or the like, and then calculate the frequency with the largest component from the frequency spectrum.

After calculating the frequency, the abnormality determiner 130 may determine whether an abnormality is present based on a comparison result between the frequency calculated from the waveform information and a reference frequency corresponding to a set value of the rotation speed of the wafer W when executing liquid processing. When the rotation speed of the wafer W is set to “N (rpm)”, the reference frequency is obtained by dividing N by 60. The abnormality determiner 130 may determine that an abnormality has occurred when the frequency calculated from the waveform information deviates from a range obtained by adding a predetermined tolerance to the reference frequency.

Determining an abnormality based on a comparison result between the frequency calculated from the waveform information and the reference frequency also includes determining an abnormality based on a comparison result between a period calculated from the waveform information and a reference period corresponding to a set value of the rotation speed. Even when determining whether an abnormality is present using the frequency calculated from the waveform information in this way, since the outer edge location calculated in the second process is included in the waveform information, whether an abnormality is present is determined based on the calculation result in the second process.

The abnormality determiner 130 may determine whether an abnormality is present based on waveform information accumulated in the calculation result accumulator 128 and a determination model constructed in advance by machine learning. The determination model is a model constructed by machine learning to output a determination result of whether an abnormality is present in response to input of information representing temporal change in the location of the outer edge Ew. If the processing conditions are the same, a periodic change in the outer edge location on the image is considered to show a similar tendency even if the individual wafer W is different, unless an abnormality occurs. For example, the determination model is constructed to capture (classify as abnormal) a case where the waveform information to be evaluated illustrates a tendency different from the periodic change in the outer edge location when normal.

The monitoring process executor 120 may include, as a functional block, a model constructor that constructs a determination model. In one example, the model constructor constructs a determination model by executing machine learning using an autoencoder based on normal data obtained by accumulating waveform information obtained during normal times when no abnormality has occurred. An autoencoder is a type of neural network, and the intermediate layer of the determination model is constructed to generate output information having the same value as the input information in response to the input information.

If the waveform information to be evaluated whose presence or absence of abnormality is unknown has a tendency close to the normal data given during learning, the output from the determination model becomes close to the waveform information to be evaluated. When the waveform information to be evaluated is input to the determination model based on the autoencoder, if no abnormality has occurred, output information with a small error from the input information is obtained. On the other hand, if an abnormality has occurred, output information with a large error from the input information is obtained. The abnormality determiner 130 may determine whether an abnormality is present according to the magnitude of the difference between the input information and the output information using a determination model constructed by machine learning using an autoencoder.

Depending on the monitoring cycle (timing at which monitoring is being executed), the range on the time axis of the waveform information obtained up to that cycle is different. Therefore, the model constructor may construct a plurality of determination models according to the timing at which monitoring is executed. The model constructor does not necessarily need to construct a different determination model for each monitoring cycle, and may construct a determination model for each range of a certain time axis. Even when determining whether an abnormality is present using such a determination model, since the outer edge location calculated in the second process is included in the waveform information to be evaluated input to the determination model, whether an abnormality is present is determined based on the calculation result in the second process.

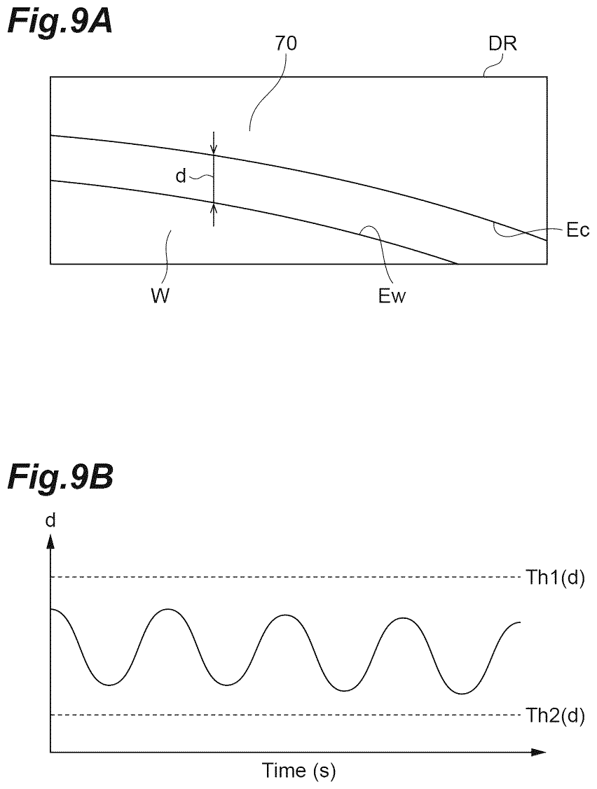

In the monitoring process, in addition to the location of the outer edge Ew of the wafer W (outer edge location), the location of the inner edge Ec of the cup 70 may be used to determine whether an abnormality is present. As illustrated in FIG. 9A, in the first process, the edge detector 124 may detect an edge corresponding to the inner edge Ec in addition to the edge corresponding to the outer edge Ew. In the second process, the outer edge location calculator 126 may calculate the location of the inner edge Ec of the cup 70 in addition to the outer edge location. In the second process, the outer edge location calculator 126 may calculate the location of the inner edge Ec of the cup 70 by the same calculation method as the calculation of the outer edge location.

The abnormality determiner 130 may determine whether an abnormality is present based on a distance d between the outer edge location and the location of the inner edge Ec calculated in the second process. FIG. 9B schematically illustrates a graph representing a temporal change in the distance d. The abnormality determiner 130 may determine that an abnormality has occurred when the distance d is greater than a first threshold value Th1(d) or smaller than a second threshold value Th2(d). Instead of comparing the distance d with a threshold value, the abnormality determiner 130 may determine whether there is an abnormality based on a comparison between a frequency obtained from waveform information representing the temporal change in the distance d and the reference frequency. The abnormality determiner 130 may determine whether an abnormality has occurred based on waveform information representing the temporal change in the distance d (waveform information at the time of evaluation) and a determination model constructed in advance by machine learning. Even when determining whether an abnormality is present using the distance d in this way, since the outer edge location calculated in the second process is used to obtain the distance d, whether an abnormality is present is determined based on the calculation result in the second process.

When the abnormality signal is output from the outputter 132, the processing controller 114 may control the rotating holder 50 to reduce the rotation speed of the wafer W instead of stopping rotation of the wafer W. When reducing the rotation speed of the wafer W, the processing controller 114 may continue processing by the liquid processing apparatus U1 in a state where the rotation speed is reduced.

The process to be monitored by the control device 100 (monitoring process executor 120) is not limited to liquid processing by the liquid processing apparatus U1. The process to be monitored may be any process as long as it involves rotation of the wafer W. The process to be monitored may be, for example, processing by a development processing apparatus. The monitoring process executor 120 does not need to be included in the control device 100. In this case, a monitoring device configured by a computer different from the control device 100 may include the monitoring process executor 120. The monitoring device may be communicably connected to the control device 100.

When comparing a magnitude relationship between two numerical values in a computer, either of the two criteria “greater than or equal to” and “greater than” may be used, and either of the two criteria “less than or equal to” and “less than” may be used. Such selection of criteria does not change a technical significance of a process of comparing the magnitude relationship between two numerical values.

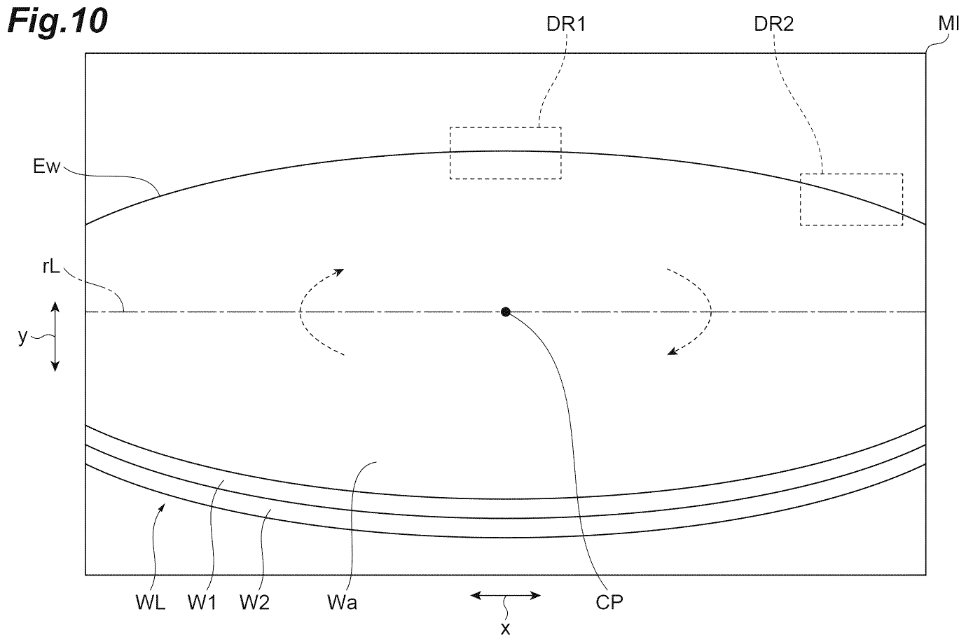

Here, with reference to FIGS. 10, 11, 12A, and 12B, a monitoring operation executed by the control device 100 during processing on a laminated substrate WL obtained by bonding two or more unit substrates to each other will be illustrated. As illustrated in FIG. 10, the laminated substrate WL (substrate) is formed, for example, by bonding a unit substrate W1 and a unit substrate W2 to each other. FIG. 10 schematically illustrates an image MI acquired by the imaging device 90 during execution of processing (predetermined processing) on the laminated substrate WL.

The outer diameter of the unit substrate W1 and the outer diameter of the unit substrate W2 may coincide with each other. The unit substrate W1 and the unit substrate W2 may be bonded so that their centers coincide with each other and main surfaces face each other. Coincidence of outer diameters and coincidence of centers each include not only a case of complete coincidence but also a case of substantial coincidence allowing a state including errors such as manufacturing errors. The unit substrate W1 and the unit substrate W2 may be bonded without an adhesive by fusion bonding, anodic bonding, or the like, or may be bonded via an adhesive.

Liquid processing on the laminated substrate WL may be executed by the liquid processing apparatus U1 having a configuration similar to the configuration illustrated in FIG. 3. The liquid processing on the laminated substrate WL may include filling a processing liquid into a gap between the unit substrate W1 and the unit substrate W2 at a peripheral edge portion of the laminated substrate WL. The rotating holder 50 of the liquid processing apparatus U1 may hold the laminated substrate WL so that the unit substrate W1 is positioned above the unit substrate W2, and rotate the laminated substrate WL. In FIG. 10, “Wa” represents the front surface of the unit substrate W1, and the front surface of the unit substrate W1 can also be said to be the front surface of the laminated substrate WL. “Ew” represents the outer edge on the front surface Wa of the laminated substrate (front surface Wa of the unit substrate W1).

The imaging device 90 may be arranged so as to be able to image the front surface Wa of the laminated substrate WL held by the holder 52 from obliquely above. In plan view, the imaging device 90 may not overlap the laminated substrate WL held by the holder 52. In plan view, a direction in which a line segment connecting the imaging device 90 and the rotation center of the holder 52 extends is defined as “depth direction”. In the depth direction, a direction (orientation) approaching the imaging device 90 is defined as “front” or “front side”, and a direction (orientation) away from the imaging device 90 is defined as “back” or “back side”. As illustrated in FIG. 10, the field of view (imaging range) of the imaging device 90 may be set to include at least a part of the outer edge Ew located on the front side of the center CP of the laminated substrate WL in the state held by the holder 52 and at least a part of the outer edge Ew located on the back side.

In FIG. 10, “rL” represents a line extending in the horizontal direction (horizontal direction on the image: x-axis direction) including the center CP of the laminated substrate WL in the image MI, and this is referred to as “reference line rL”. A detection target region DR representing a partial region to be subjected to edge detection may be set above the reference line rL in the image MI. Above the reference line rL in the image MI corresponds to the back side of the center CP of the laminated substrate WL in the state held by the holder 52 in the depth direction. In the image MI, above the reference line rL, the outer edge of the unit substrate W1 positioned above may be observed, and below the reference line rL, the outer edges (outer peripheral surfaces) of each of the unit substrate W1 and the unit substrate W2 may be observed.

Two or more detection target regions DR may be set, and in the first process, the edge detector 124 may detect edges in each of the two or more detection target regions DR. For example, as the two or more detection target regions DR, a detection target region DR1 and a detection target region DR2 are set above the reference line rL in the image MI. In the horizontal direction on the image, some part of the detection target region DR1 overlaps the location of the center CP, and the entire detection target region DR2 does not overlap the location of the center CP.

In the second process, the outer edge location calculator 126 may calculate the location of the outer edge Ew in the vertical direction (y-axis direction) on the image from the edge detected in the detection target region DR1. In the second process, the outer edge location calculator 126 may calculate the location of the outer edge Ew in the horizontal direction (x-axis direction) on the image from the edge detected in the detection target region DR2. In the detection target region DR1, fluctuation in the location of the outer edge Ew in the vertical direction is more readily observed than in the detection target region DR2. In the detection target region DR2, fluctuation in the location of the outer edge Ew in the horizontal direction is more readily observed than in the detection target region DR1.

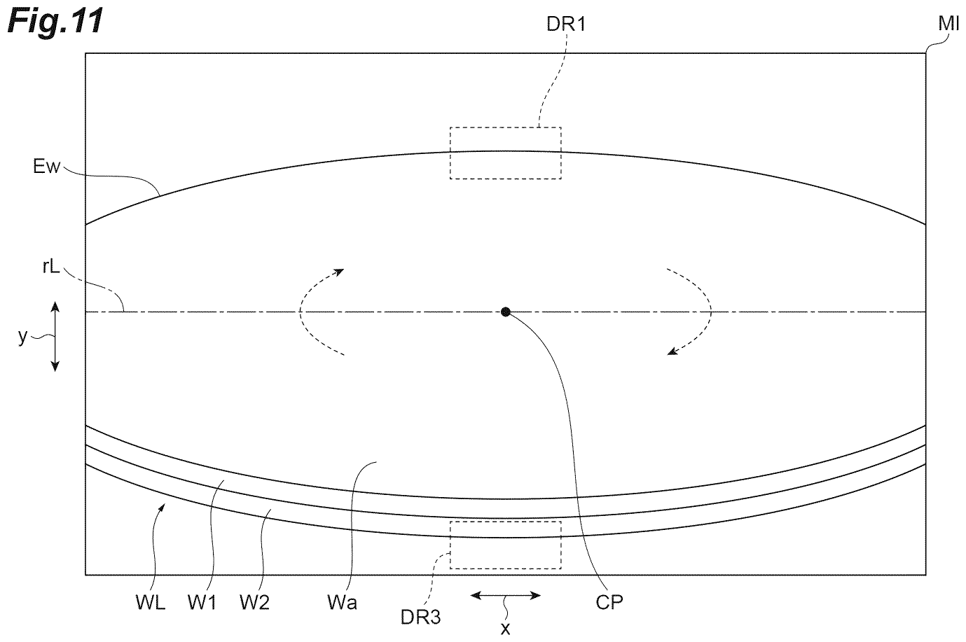

Unlike the example illustrated in FIG. 10, as illustrated in FIG. 11, two detection target regions DR may be set above and below the reference line rL in the image MI, respectively. The detection target region DR1 is set above the reference line rL in the image MI, and the detection target region DR3 is set below the reference line rL in the image MI. The detection target region DR3 may be set to include the outer edge of the unit substrate (unit substrate W2 in the example of FIG. 11) positioned at the bottom of the laminated substrate WL and not include the outer edges of other unit substrates. As a result, even if the number of unit substrates included in the laminated substrate WL changes, edge detection can be performed without changing the position of the detection target region DR3. Focusing on the monitoring process using the detection target region DR3, in the first process, the outer edge on the back surface (lower surface) of the unit substrate W2 may be detected as an edge instead of the front surface Wa of the laminated substrate WL (front surface Wa of the unit substrate W1).

The monitoring process including the first process, the second process, and the third process may be executed during a period when the laminated substrate WL is not rotating. For example, the control device 100 may execute the monitoring process during at least one of a period during which the laminated substrate WL is moved upward by the plurality of lift pins 58 and after the laminated substrate WL is moved upward. The control device 100 may repeat the monitoring process after moving the laminated substrate WL upward, or may perform one monitoring process.

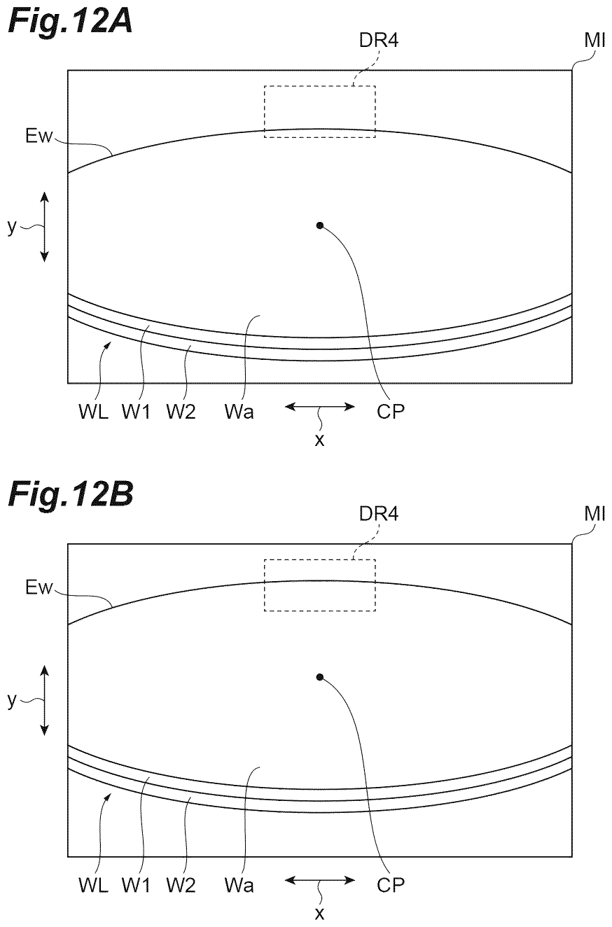

FIGS. 12A and 12B schematically illustrate images MI used when performing the monitoring process after moving the laminated substrate WL upward by the plurality of lift pins 58. The image MI illustrated in FIG. 12A is an image obtained by imaging the state of the laminated substrate WL before movement (in the state held by the holder 52). The image MI illustrated in FIG. 12B is an image obtained by imaging the state of the laminated substrate WL supported by the plurality of lift pins 58 after being raised by the plurality of lift pins 58.

The edge detector 124 may detect an edge in a detection target region DR4, which is an example of the detection target region DR. The detection target region DR4 may be set to include a part of the outer edge of the laminated substrate WL in the state raised by the plurality of lift pins 58. The detection target region DR4 may or may not include a part of the outer edge of the laminated substrate WL before being raised. In the second process, the outer edge location calculator 126 may calculate at least the location of the outer edge Ew in the vertical direction (y-axis direction) on the image from the edge detected in the detection target region DR4.

In the third process, the abnormality determiner 130 may determine whether an abnormality related to raising of the laminated substrate WL is present based on a result of comparing the calculated value of the location of the outer edge Ew in the vertical direction on the image with a normal range obtained by adding a tolerance to a predetermined normal location. The predetermined normal location and tolerance (that is, the normal range) may be determined by prior experiments. The abnormality determiner 130 may determine that it is abnormal when the calculated value of the location of the outer edge Ew deviates from the normal range, and may determine that it is normal (not abnormal) when the calculated value of the location of the outer edge Ew is included in the normal range.

In one example among the various examples described above, at least a part of the matters described in other examples may be combined. For example, a plurality of types of abnormality determination methods (comparison between outer edge location and threshold value, comparison of frequency, use of determination model, and use of distance from the cup) may be combined.

### Summary of Present Disclosure

The present disclosure includes the configurations of the following [1] to [22] and the configurations of Supplementary Notes 1 to 3. A configuration of any of Supplementary Notes 1 to 3 may be combined with the configuration described in any of [1] to [22].
[1] A substrate processing method including: executing a predetermined process on a substrate (W, WL), wherein the predetermined process includes rotating the substrate (W, WL) held by a holder (52); and repeatedly executing a monitoring process during execution of the predetermined process, wherein the monitoring process includes: a first process of detecting an outer edge (Ew) in an image (MI) acquired by imaging a range including the outer edge (Ew) on a front surface (Wa) of the substrate (W, WL); a second process of calculating a location of the outer edge (Ew) in the image (MI) based on a detection result of the first process; and a third process of determining whether an abnormality related to holding of the substrate (W, WL) by the holder (52) is present, based on a calculation result of the second process. As described above, when the fluctuation in the temporal change in the location of the outer edge (Ew) in the image (MI) is large, it can be determined that some abnormality has occurred in holding of the substrate (W, WL) by the holder (52). In the substrate processing method, since determination of whether an abnormality is present based on the location of the outer edge (Ew) is repeatedly performed during execution of processing, an abnormality related to holding of the substrate (W, WL) can be detected during processing when it occurs. As a result, it may be possible to avoid continuing processing in a state where an abnormality that may cause damage to the substrate (W, WL) has occurred. Therefore, occurrence of trouble during substrate processing (for example, damage to the substrate (W, WL)) can be prevented.
[2] The substrate processing method according to [1], wherein the substrate (WL) to be processed in the predetermined process is a laminated substrate (WL) in which two or more unit substrates (W1, W2) are bonded to each other. The weight of the laminated substrate (WL) is larger than that of a substrate composed of one unit substrate. Therefore, even if the degree of displacement between the rotation center during processing and the center (CP) of the laminated substrate (WL) is small, there is a possibility that an abnormality related to holding may occur. Therefore, it is more beneficial to execute the monitoring process during execution of the predetermined process on the laminated substrate (WL).
[3] The substrate processing method according to [2], wherein the image (MI) is acquired by imaging with an imaging device (90) arranged obliquely above the laminated substrate (WL), wherein in the first process, a partial region (DR, DR1, DR2) of the image (MI) is extracted, and the outer edge (Ew) is detected in the partial region (DR, DR1, DR2), and wherein the partial region (DR, DR1, DR2) is set, in the image (MI), above a horizontal reference line (rL) including a center (CP) of the laminated substrate (WL). The outer edge (Ew) observed above the reference line (rL) in the image (MI) is a boundary between the front surface (Wa) of the laminated substrate (WL) and a region outside the laminated substrate (WL). On the other hand, the outer edge (Ew) observed below the reference line (rL) in the image (MI) is a boundary between the front surface (Wa) and an end surface (peripheral surface) of the laminated substrate (WL). Therefore, above the reference line (rL), the contrast of the outer edge (edge) portion on the image is larger than below. As a result, the location of the outer edge (Ew) of the laminated substrate (WL) can be calculated with high accuracy.
[4] The substrate processing method according to any one of [1] to [3], further including, when the abnormality is detected in the monitoring process, reducing a rotation speed of the substrate (W, WL) held by the holder (52) or stopping rotation of the substrate (W, WL) held by the holder (52) during execution of the predetermined process. In this case, it may be possible to more reliably avoid continuing processing in a state where an abnormality has occurred.
[5] The substrate processing method according to [1] or [2], wherein in the first process, a partial region (DR) of the image (MI) is extracted, and the outer edge (Ew) is detected in the partial region (DR). Although it is assumed that an image (MI) is acquired for purposes other than the monitoring process, there are cases where the range of the image necessary for other purposes and the range of the image necessary for the monitoring process do not match. In the above method, since the monitoring process is executed using the partial region (DR), it may be possible to achieve both the monitoring process and acquisition of an image for other purposes.
[6] The substrate processing method according to any one of [1] to [5], wherein in the third process, whether the abnormality is present is determined based on a comparison result between the location of the outer edge (Ew) calculated in the second process and a predetermined threshold value (Th1, Th2). When the location of the outer edge (Ew) fluctuates greatly, it is assumed that an abnormality has occurred in holding of the substrate (W, WL). In the above method, an abnormality occurring in holding of the substrate (W, WL) can be detected by simple processing of comparing the outer edge location with a threshold value.
[7] The substrate processing method according to any one of [1] to [6], wherein the third process includes: calculating a frequency in waveform information representing a temporal change in the location of the outer edge (Ew) obtained before execution of the third process; and determining whether the abnormality is present based on a comparison result between the frequency calculated from the waveform information and a reference frequency corresponding to a set value of a rotation speed of the substrate (W, WL) when executing the predetermined process. In this case, an abnormality that cannot be determined only by the degree of fluctuation in the outer edge location can be detected.
[8] The substrate processing method according to any one of [1] to [7], wherein in the third process, whether the abnormality is present is determined based on: a determination model constructed in advance by machine learning, wherein the determination model is configured to output a determination result of whether the abnormality is present in response to an input of information representing a temporal change in the location of the outer edge (Ew); and waveform information representing a temporal change in the location of the outer edge (Ew) obtained before execution of the third process. In this case, an abnormality that cannot be determined only by the degree of fluctuation in the outer edge location can be detected.
[9] The substrate processing method according to any one of [1] to [8], wherein the predetermined process includes a liquid processing, and the liquid processing includes supplying a processing liquid (L1) to the substrate (W, WL) held by the holder (52), wherein the holder (52) is surrounded by a cup (70) that receives the processing liquid (L1) after being supplied to the substrate (W, WL), wherein in the second process, in addition to the location of the outer edge (Ew), a location of an inner edge (Ec) of the cup (70) is calculated, and wherein in the third process, whether the abnormality is present is determined based on a distance (d) between the location of the outer edge (Ew) and the location of the inner edge (Ec) calculated in the second process. In this case, an abnormality that cannot be determined only by the degree of fluctuation in the outer edge location can be detected.
[10] The substrate processing method according to any one of [1] to [9], wherein in the second process, the location of the outer edge (Ew) is calculated by obtaining an average value of coordinates of a plurality of points detected as the outer edge (Ew) in the first process. In the image (MI), the boundary between the substrate (W, WL) and another region is not necessarily clear, and noise may be included in the detection result of the outer edge (Ew) in the first process. Even when noise is included, by obtaining an average value, the influence on the calculated value of the outer edge location can be reduced. As a result, detection of an abnormality based on the outer edge location can be performed with high accuracy.
[11] The substrate processing method according to any one of [1] to [10], wherein the second process includes calculating a horizontal location and a vertical location of the outer edge (Ew) in the image (MI), and wherein the third process includes: determining, for each of a horizontal direction and a vertical direction, whether the abnormality is present; and determining that the abnormality is present, when the abnormality is detected in either the horizontal direction or the vertical direction. Since it is determined that there is an abnormality when the calculation result of the outer edge location indicates an abnormality in one of the horizontal direction and the vertical direction, occurrence of an abnormality can be detected more reliably.
[12] A monitoring method of substrate processing, including: repeatedly executing a monitoring process while a predetermined process including rotating a substrate (W, WL) held by a holder (52) is being performed on the substrate (W, WL), wherein the monitoring process includes: a first process of detecting an outer edge (Ew) in an image (MI) acquired by imaging a range including the outer edge (Ew) on a front surface (Wa) of the substrate (W, WL); a second process of calculating a location of the outer edge (Ew) in the image (MI) based on a detection result of the first process; and a third process of determining whether an abnormality related to holding of the substrate (W, WL) by the holder (52) is present, based on a calculation result of the second process. This monitoring method of substrate processing can prevent occurrence of trouble during substrate processing, similarly to the substrate processing method.
[13] The monitoring method according to [12], further including, when the abnormality is detected in the monitoring process, reducing a rotation speed of the substrate (W, WL) held by the holder (52) or stopping rotation of the substrate (W, WL) held by the holder (52) during execution of the predetermined process. In this case, it may be possible to more reliably avoid continuing processing in a state where an abnormality has occurred.
[14] The monitoring method according to [12] or [13], wherein in the first process, a partial region (DR) of the image (MI) is extracted, and the outer edge (Ew) is detected in the partial region (DR). Although it is assumed that an image (MI) is acquired for purposes other than the monitoring process, there are cases where the range of the image necessary for other purposes and the range of the image necessary for the monitoring process do not match. In the above method, since the monitoring process is executed using the partial region (DR), it may be possible to achieve both the monitoring process and acquisition of an image for other purposes.
[15] The monitoring method according to any one of [12] to [14], wherein in the third process, whether the abnormality is present is determined based on a comparison result between the location of the outer edge (Ew) calculated in the second process and a predetermined threshold value (Th1, Th2). When the location of the outer edge (Ew) fluctuates greatly, it is assumed that an abnormality has occurred in holding of the substrate (W, WL). In the above method, an abnormality occurring in holding of the substrate (W, WL) can be detected by simple processing of comparing the outer edge location with a threshold value.
[16] The monitoring method according to any one of [12] to [15], wherein the third process includes: calculating a frequency in waveform information representing a temporal change in the location of the outer edge (Ew) obtained before execution of the third process; and determining whether the abnormality is present based on a comparison result between the frequency calculated from the waveform information and a reference frequency corresponding to a set value of a rotation speed of the substrate (W, WL) when executing the predetermined process. In this case, an abnormality that cannot be determined only by the degree of fluctuation in the outer edge location can be detected.
[17] The monitoring method according to any one of [12] to [16], wherein in the third process, whether the abnormality is present is determined based on: a determination model constructed in advance by machine learning, wherein the determination model is configured to output a determination result of whether the abnormality is present in response to an input of information representing a temporal change in the location of the outer edge (Ew); and waveform information representing a temporal change in the location of the outer edge (Ew) obtained before execution of the third process. In this case, an abnormality that cannot be determined only by the degree of fluctuation in the outer edge location can be detected.
[18] The monitoring method according to any one of [12] to [17], wherein the predetermined process includes a liquid processing, and the liquid processing includes supplying a processing liquid (L1) to the substrate (W, WL) held by the holder (52), wherein the holder (52) is surrounded by a cup (70) that receives the processing liquid (L1) after being supplied to the substrate (W, WL), wherein in the second process, in addition to the location of the outer edge (Ew), a location of an inner edge (Ec) of the cup (70) is calculated, and wherein in the third process, whether the abnormality is present is determined based on a distance (d) between the location of the outer edge (Ew) and the location of the inner edge (Ec) calculated in the second process. In this case, an abnormality that cannot be determined only by the degree of fluctuation in the outer edge location can be detected.
[19] The monitoring method according to any one of [12] to [18], wherein in the second process, the location of the outer edge (Ew) is calculated by obtaining an average value of coordinates of a plurality of points detected as the outer edge (Ew) in the first process. In the image (MI), the boundary between the substrate (W, WL) and another region is not necessarily clear, and noise may be included in the detection result of the outer edge (Ew) in the first process. Even when noise is included, by obtaining an average value, the influence on the calculated value of the outer edge location can be reduced. As a result, detection of an abnormality based on the outer edge location can be performed with high accuracy.
[20] The monitoring method according to any one of [12] to [19], wherein the second process includes calculating a horizontal location and a vertical location of the outer edge (Ew) in the image (MI), and wherein the third process includes: determining, for each of a horizontal direction and a vertical direction, whether the abnormality is present; and determining that the abnormality is present, when the abnormality is detected in either the horizontal direction or the vertical direction. Since it is determined that there is an abnormality when the calculation result of the outer edge location indicates an abnormality in one of the horizontal direction and the vertical direction, occurrence of an abnormality can be detected more reliably.
[21] A computer-readable storage medium storing a program for causing an apparatus to execute the substrate processing method according to any one of [1] to [11] or the monitoring method according to any one of [12] to [20]. This storage medium can prevent occurrence of trouble during substrate processing, similarly to the substrate processing method.
[22] A substrate processing apparatus (1) including: a processing unit (U1) configured to execute a predetermined process on a substrate (W, WL), the predetermined process including rotating the substrate (W, WL) held by a holder (52); and a monitoring process executor (120) configured to repeatedly execute a monitoring process during execution of the predetermined process, wherein the monitoring process includes: a first process of detecting an outer edge (Ew) in an image (MI) acquired by imaging a range including the outer edge (Ew) on a front surface (Wa) of the substrate (W, WL); a second process of calculating a location of the outer edge (Ew) in the image (MI) based on a detection result of the first process; and a third process of determining whether an abnormality related to holding of the substrate (W, WL) by the holder (52) is present, based on a calculation result of the second process. This substrate processing apparatus (1) can prevent occurrence of trouble during substrate processing, similarly to the substrate processing method.
Supplementary Note 1. A substrate processing method including: performing a predetermined process on a laminated substrate (WL) in which two or more unit substrates (W1, W2) are bonded to each other; and repeatedly executing a monitoring process during execution of the predetermined process, wherein the monitoring process includes: a first process of detecting an outer edge (edge) in an image (MI) acquired by imaging a range including the outer edge of the laminated substrate (WL); a second process of calculating a location of the outer edge in the image (MI) based on a detection result of the first process; and a third process of determining whether an abnormality in the predetermined process is present based on a calculation result of the second process, and a substrate processing apparatus that executes the substrate processing.
Supplementary Note 2. A substrate processing method including: performing a predetermined process on a laminated substrate (WL) in which two or more unit substrates (W1, W2) are bonded to each other; and during execution of the predetermined process, executing a first process of detecting an outer edge (edge) in an image (MI) acquired by imaging a range including the outer edge of the laminated substrate (WL), a second process of calculating a location of the outer edge in the image (MI) based on a detection result of the first process, and a third process of determining whether an abnormality in the predetermined process is present based on a calculation result of the second process, wherein the predetermined process includes moving the laminated substrate (WL) upward and supporting the laminated substrate (WL) in the state moved upward.
Supplementary Note 3. The substrate processing method and substrate processing apparatus according to Supplementary Note 1 or 2, wherein in the first process, the outer edge (Ew) on the front surface (Wa) of the laminated substrate (WL) is detected.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A substrate processing method comprising:
executing a predetermined process on a substrate, wherein the predetermined process comprises rotating the substrate held by a holder; and
repeatedly executing a monitoring process during execution of the predetermined process,
wherein the monitoring process comprises:
a first process of detecting an outer edge in an image acquired by imaging a range including the outer edge on a front surface of the substrate;
a second process of calculating a location of the outer edge in the image based on a detection result of the first process; and
a third process of determining whether an abnormality related to holding of the substrate by the holder is present, based on a calculation result of the second process.

2. The substrate processing method according to claim 1, wherein the substrate to be processed in the predetermined process is a single substrate.

3. The substrate processing method according to claim 1, wherein the substrate to be processed in the predetermined process is a laminated substrate in which two or more unit substrates are bonded to each other.

4. The substrate processing method according to claim 3, wherein the image is acquired by imaging with an imaging device arranged obliquely above the laminated substrate,
wherein in the first process, a partial region of the image is extracted, and the outer edge is detected in the partial region, and
wherein the partial region is set, in the image, above a horizontal reference line including a center of the laminated substrate.

5. The substrate processing method according to claim 1, further comprising:
when the abnormality is detected in the monitoring process, reducing a rotation speed of the substrate held by the holder during the execution of the predetermined process.

6. The substrate processing method according to claim 1, further comprising:
when the abnormality is detected in the monitoring process, stopping rotation of the substrate held by the holder during the execution of the predetermined process.

7. The substrate processing method according to claim 1, wherein in the first process, a partial region of the image is extracted, and the outer edge is detected in the partial region.

8. The substrate processing method according to claim 7, further comprising:
executing a second monitoring process during the execution of the predetermined process,
wherein the second monitoring process comprises monitoring or recording a processing status of the predetermined process using an entire of the image.

9. The substrate processing method according to claim 1, wherein in the third process, whether the abnormality is present is determined based on a comparison result between the location of the outer edge calculated in the second process and a predetermined threshold value.

10. The substrate processing method according to claim 9, wherein the third process comprises determining the abnormality is present when:
the location of the outer edge calculated in the second process exceeds a first threshold value; or
the location of the outer edge calculated in the second process falls below a second threshold value smaller than the first threshold value.

11. The substrate processing method according to claim 1, wherein the third process comprises:
calculating a frequency in waveform information representing a temporal change in the location of the outer edge obtained before execution of the third process; and
determining whether the abnormality is present based on a comparison result between the frequency calculated from the waveform information and a reference frequency corresponding to a set value of a rotation speed of the substrate when executing the predetermined process.

12. The substrate processing method according to claim 1, wherein in the third process, whether the abnormality is present is determined based on:
a determination model constructed in advance by machine learning, wherein the determination model is configured to output a determination result of whether the abnormality is present in response to an input of information representing a temporal change in the location of the outer edge; and
waveform information representing a temporal change in the location of the outer edge obtained before execution of the third process.

13. The substrate processing method according to claim 1,
wherein the predetermined process comprises a liquid processing, and
the liquid processing comprises supplying a processing liquid to the substrate held by the holder.

14. The substrate processing method according to claim 13,
wherein the liquid processing further comprises rotating the substrate to dry a film of the processing liquid after supplying the processing liquid, and
wherein the monitoring process is executed repeatedly during a period in which the substrate is rotated to dry the film.

15. The substrate processing method according to claim 13, wherein the holder is surrounded by a cup that is configured to receive the processing liquid after being supplied to the substrate,
wherein in the second process, in addition to the location of the outer edge, a location of an inner edge of the cup is calculated, and
wherein in the third process, whether the abnormality is present is determined based on a distance between the location of the outer edge and the location of the inner edge calculated in the second process.

16. The substrate processing method according to claim 1, wherein in the second process, the location of the outer edge is calculated based on coordinates of a plurality of points detected as the outer edge in the first process.

17. The substrate processing method according to claim 16, wherein in the second process, the location of the outer edge is calculated by obtaining an average value of the coordinates of the plurality of points detected as the outer edge in the first process.

18. The substrate processing method according to claim 1,
wherein the second process comprises calculating a horizontal location and a vertical location of the outer edge in the image, and
wherein the third process comprises:
determining, for each of a horizontal direction and a vertical direction, whether the abnormality is present; and
determining that the abnormality is present, when the abnormality is detected in either the horizontal direction or the vertical direction.

19. A computer-readable storage medium storing a program for causing an apparatus to execute a monitoring method of substrate processing, the monitoring method comprising:
repeatedly executing a monitoring process while a predetermined process is being performed on a substrate, the predetermined process including rotating the substrate held by a holder,
wherein the monitoring process comprises:
a first process of detecting an outer edge in an image acquired by imaging a range including the outer edge on a front surface of the substrate;
a second process of calculating a location of the outer edge in the image based on a detection result of the first process; and
a third process of determining whether an abnormality related to holding of the substrate by the holder is present, based on a calculation result of the second process.

20. A substrate processing apparatus comprising circuitry configured to:
execute a predetermined process on a substrate, wherein the predetermined process comprises rotating the substrate held by a holder; and
repeatedly execute a monitoring process during execution of the predetermined process,
wherein the monitoring process comprises:
a first process of detecting an outer edge in an image acquired by imaging a range including the outer edge on a front surface of the substrate;
a second process of calculating a location of the outer edge in the image based on a detection result of the first process; and
a third process of determining whether an abnormality related to holding of the substrate by the holder is present, based on a calculation result of the second process.
